(19) United States
(12) Patent Application Publication
(10) Pub. No.: US 2024/0381546 A1
(43) Pub. Date: Nov. 14, 2024

(54) PLUG-IN CONNECTING DEVICE FOR A MOTOR VEHICLE

(71) Applicant: BROSE FAHRZEUGTEILE SE & CO. KOMMANDITGESELLSCHAFT, COBURG, Coburg (DE)

(72) Inventors: Katharina WOLFAHRT, Ebersdorf (DE); Jochen HOFMANN, Marktgraitz (DE); Rene SCHEEDE, Bamberg (DE); Alexander CZEMPIK, Markkleeberg (DE); Jens WINTER, Coburg (DE); Stefan HIELTSCHER, Bamberg (DE); Steve EBERLEIN, Hallstadt (DE); Florian POHL, Ebersdorf (DE); Thorsten KUHNEN, Litzendorf (DE)

(21) Appl. No.: 18/688,245

(22) PCT Filed: Aug. 29, 2022
(86) PCT No.: PCT/EP2022/073878

§ 371 Date: Apr. 8, 2024

(30) Foreign Application Priority Data
Sep. 1, 2021 (DE) 10 2021 209 611.5

(51) Int. Cl. H05K 5/00; B60R 16/023

(52) U.S. Cl. CPC H05K 5/0069; B60R 16/023; H05K 5/0052

(57) ABSTRACT

It is provided a plug-in connecting device for a motor vehicle, comprising a housing comprising a plug-in opening, a printed circuit board that is arranged in the housing and comprises a plug-in portion in the region of an edge of the printed circuit board, and a plug-in connector part, which can be plugged into the plug-in opening in the housing in a plug-in direction such that it electrically contacts the plug-in portion of the printed circuit board. In this case, it is provided that the plug-in connector part comprises at least one stop which strikes at least one stop on the housing in the plug-in direction.

### BACKGROUND

The proposed solution relates to a plug-in connecting device for a motor vehicle as well as to an adjustment apparatus and to a motor vehicle comprising a plug-in connecting device of this type.

A plug-in connecting device of this type comprises a housing having a plug-in opening, a printed circuit board that is arranged in the housing and comprises a plug-in portion in the region of an edge of the printed circuit board, and a plug-in connector part, which can be plugged into the plug-in opening in the housing in a plug-in direction such that it electrically contacts the plug-in portion of the printed circuit board.

A plug-in connecting device of this type is described in DE 10 2010 025 086 A1.

Printed circuit board edge contacting often has the advantage that an additional plug-in body can be omitted, which in particular allows for a compact arrangement.

### SUMMARY

The object underlying the proposed solution is that of providing an improved plug-in connecting device.

This object is achieved by means of subject-matter having features as described herein.

Accordingly, it is provided that the plug-in connector part comprises at least one stop which strikes at least one stop on the housing in the plug-in direction.

This makes it possible for forces acting on the plug-in connector part in the plug-in direction not to be transmitted, or only to be transmitted to a negligible extent, to the printed circuit board, and instead for them to be able to be dissipated via the housing. This therefore allows the printed circuit board to be made of a thinner material, meaning that weight and installation space can also be saved, and allows for a particularly robust configuration and extended service life of the plug-in connecting device.

For example, the stop on the housing and the stop on the plug-in connector part are arranged and configured such that, during a plug-in process involving a movement of the plug-in connector part in the plug-in direction into the plug-in opening, the stop on the plug-in connector part strikes the stop on the housing, and specifically in particular before the plug-in connector part comes into contact with the edge of the printed circuit board, in particular an edge surface of the printed circuit board perpendicular to the plug-in direction. This can effectively prevent force from being transmitted from the plug-in connector part to the printed circuit board. In addition, this solution allows for a particularly simple construction having few components.

It can be provided that the stop on the housing, when viewed in the plug-in direction, is arranged in front of the edge of the printed circuit board. A stop surface of the stop is e.g. arranged to be offset from the edge surface of the printed circuit board (and e.g. parallel thereto).

In one configuration, the plug-in connector part comprises a body, on which a plurality of contacts are mounted, wherein the body is spaced apart from the edge of the printed circuit board in a plugged-in state of the plug-in connector part when viewed in the plug-in direction. For example, the body does not touch the edge surface. The printed circuit board comprises two parallel main surfaces, which are interconnected by edge surfaces. For example, in the plugged-in state, the body of the plug-in connector part touches one or both of the main surfaces of the printed circuit board, but not the edge surfaces. Owing to a spacing of this type, in particular in the form of a gap, force can be prevented from being transmitted to the printed circuit board particularly effectively.

In one configuration, a latch element is formed on the housing, which latch element is configured and provided to latch to a latch element formed on the plug-in connector part in order to prevent the plug-in connector part from being pulled out counter to the plug-in direction. Since the latch element is formed on the housing, and not on the printed circuit board, for example, when a force is acting counter to the plug-in direction, e.g. a pulling force on the plug-in connector part, force can be prevented or substantially prevented from being transmitted to the printed circuit board.

In one development, the latch element of the housing is arranged in a plane together with the printed circuit board. For example, the latch element is arranged in front of or beside the printed circuit board in the projection direction of the printed circuit board. The latch element thus e.g. lies in an imaginary extension of the printed circuit board. As a result, loads caused by misuse and use can be dissipated into the housing without any tilting relative to the printed circuit board.

Optionally, the latch element of the plug-in connector part is configured to be flexible and the latch element of the housing is configured to be rigid. Alternatively, the latch element of the plug-in connector part is configured to be rigid and the latch element of the housing is configured to be flexible. For example, the latch element on the plug-in connector part is in the form of a flexible latch arm, and resiliently snaps behind the latch element on the housing, which is configured as a latch rim, when plugging the plug-in connector part into the plug-in portion of the printed circuit board.

The housing can comprise two housing parts. In this case, it can be provided that fastening points are configured for fastening the housing to another component on those housing parts on which the latch element and/or the stop on the housing is/are also formed. As a result, forces can be effectively dissipated by means of the housing part, which is e.g. in the form of a housing shell. The other of the two housing parts acts e.g. as a cover, via which no forces are then dissipated, or are only dissipated to a negligible extent, for example. Alternatively, the housing is formed in one piece.

The housing can comprise a collar, which is configured to laterally support the plug-in connector part in the plugged-in state. As a result, laterally directed forces and torques can be dissipated into the housing. One part of the collar is e.g. formed in one housing part and the other part is formed in the other housing part. This allows for particularly simple mounting and a flat design. Alternatively, the collar is formed by a single housing part, which allows for a particularly high loading capacity.

It can be provided that the plug-in connector part engages around a corner of the printed circuit board in the plugged-in state. This allows for a particularly compact configuration.

A cable attached to the plug-in connector part can be held e.g. on a holder of the housing by means of an optional strain relief device. In this way, higher tensile loads can also be dissipated via the housing without forces being transmitted to the printed circuit board.

At least one portion of the housing can be inclined towards the printed circuit board in the region of the plug-in opening. As a result, the plug-in connector part can be brought into the plugged-in state.

The printed circuit board can be rigidly connected to the housing, or can be held thereon by a mount that is flexible or has clearance.

The housing can comprise a motor receptacle for fastening a motor. Modules for a motor controller are provided on the printed circuit board, for example. Since the motor can exert forces, the above-mentioned advantageous take particular effect in this case.

Optionally, a surface, in particular a gold-plated surface, of the printed circuit board is tin-plated in the region of the plug-in portion, for example. For example, contact surfaces are tin-plated in the plug-in portion of the printed circuit board. Gold-plated surfaces mean that the printed circuit board does not need to be immediately soldered. Contacts on the plug-in connector part can be tin-plated for corrosion protection, which could result in undesired effects when combined with gold-plated contact surfaces. When the gold-plated contact surfaces are tin-plated beforehand, both advantages can be utilized.

According to one aspect, an adjustment apparatus is provided. The adjustment apparatus comprises the plug-in connecting device in accordance with any configuration described herein and a motor mounted on the housing. The motor is e.g. a brushless motor. The printed circuit board supports e.g. modules of a control unit for the motor.

According to one aspect, a motor vehicle is provided, comprising the plug-in connecting device in accordance with any configuration described herein and/or the adjustment apparatus in accordance with any configuration described herein.

### BRIEF DESCRIPTION OF THE DRAWINGS

The concept underlying the solution will be explained in greater detail in the following with reference to the exemplary embodiments shown in the drawings, in which:

FIG. 1 is a view of a motor vehicle comprising a vehicle seat, a door and a plurality of plug-in connecting devices.

FIG. 2 is a perspective view of one of the plug-in connecting devices according to FIG. 1 comprising a housing and a plug-in connector part.

FIG. 3 is a plan view of the top of the plug-in connecting device according to FIG. 2.

FIG. 4 is an exploded view of the plug-in connecting device according to FIG. 2.

FIG. 5 is a perspective view of the plug-in connecting device according to FIG. 2, wherein a cover of the housing has been removed and a printed circuit board arranged in the housing is visible as a result.

FIG. 6 is a plan view of the top of the plug-in connecting device without a cover according to FIG. 5.

FIG. 7 is an enlarged detail A of FIG. 6.

FIG. 8 is the view according to FIG. 6, wherein the plug-in connector part has been removed.

FIG. 9 is an enlarged detail B of FIG. 8.

FIG. 10 is a plan view of the front of the plug-in connecting device according to FIG. 2.

FIG. 11 is an enlarged detail C of FIG. 10.

FIGS. 12 and 13 show perspective views of the plug-in connector part shown in FIGS. 2 to 8.

FIG. 14 is a side view of the printed circuit board having the plug-in connector part according to FIG. 2 plugged into it.

### DETAILED DESCRIPTION

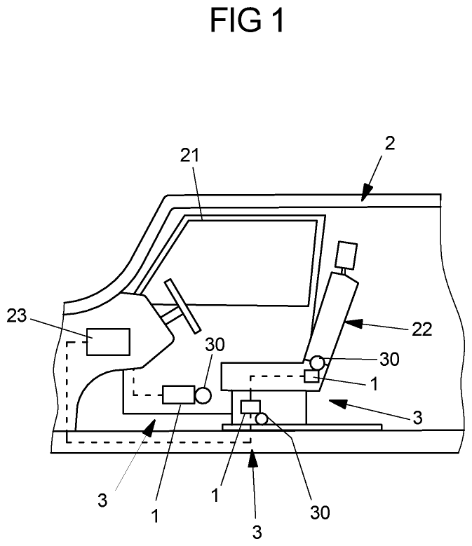

FIG. 1 is a detail of a motor vehicle 2 comprising a chassis 20 and a plurality of adjustment apparatuses 3. One adjustment apparatus 3 is configured as a window regulator for a window of a door 21. Another adjustment apparatus 3 is configured as a longitudinal adjustment apparatus for a vehicle seat 22. Another adjustment apparatus is configured as a rake adjuster for a backrest of the vehicle seat 22.

Each of the adjustment apparatuses 3 comprises a plug-in connecting device 1 and a motor 30. Each plug-in connecting device 1 is connected to a cable, and specifically via a plug-in connection described in greater detail in the following. In the example shown, the cable, shown here in the form of dashed lines, leads to a control unit 23, which supplies the adjustment apparatuses 3 with signals and/or operating current.

The motor 30 of the respective adjustment apparatuses 3 brings about an adjustment of the corresponding component to be adjusted. The motor is actuated and/or supplied with operating current by electronics provided in the relevant plug-in connecting device 1. These electronics are therefore e.g. a motor controller.

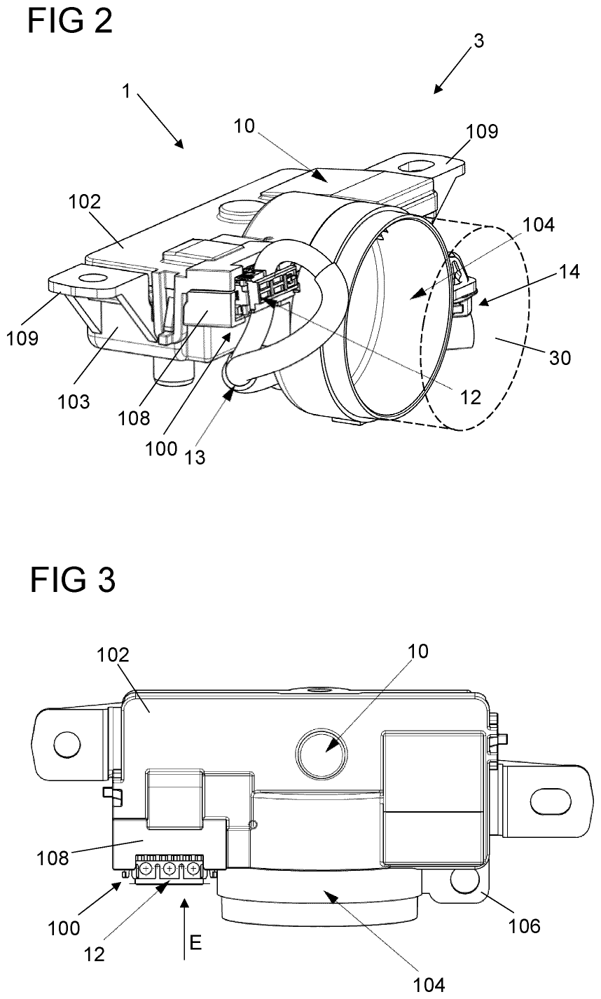

FIG. 2 shows one of the adjustment apparatuses 3 in detail. It can be seen in this figure that the plug-in connecting device 1 comprises a housing 10. The housing 10 forms a plug-in opening 100. In the state shown in FIG. 1, a plug-in connector part 12 is plugged into the plug-in opening 100. For this purpose, the housing 10 forms a collar 108, which laterally supports the plugged-in plug-in connector part 12.

A cable 13 is connected to the plug-in connector part 12. The cable provides bus cabling. In the present case, the cable 13 forms a loop through the plug-in connector part 12 and can thus be connected to another plug-in connector part in series. For instance, a plurality of adjustment apparatuses 3 can be supplied with signals and/or operating current via the same cable 13, as provided in the motor vehicle 2 according to FIG. 1 and as shown by way of example for the two shown adjustment apparatuses 3 of the vehicle seat 22. As a result, a considerable length of cable can be saved.

A strain relief device 14 additionally secures the cable 13 to the housing 10. In this example, the strain relief device 14 comprises a clamp which surrounds the cable 13 and is fixed to a holder 106 (see e.g. FIG. 3). The holder 106 is formed by a tab comprising a fastening hole.

The housing 10 comprises a first housing part 102 and a second housing part 103. The second housing part 103 acts as a housing shell and the first housing part 102 acts as a cover for the housing shell. The housing 10 forms a motor receptacle 104 for the motor 30 of the adjustment apparatus 3. The motor receptacle 104 is round in this example. The motor receptacle 104 is suitable for receiving a brushless motor. The motor controller of the motor 30 is accommodated in the interior of the housing 10.

The collar 108 and the plug-in opening 100 are formed together by the two housing parts 102, 103. Both the first housing part 102 and the second housing part 103 each form part of the collar 108 and define the plug-in opening 100 in part.

The housing 10, more specifically the second housing part 103, further comprises a plurality of fastening points 109. In the present case, the fastening points 109 are each in the form of a tab comprising a screw hole. The housing 10 can be mounted to a point provided for this purpose, e.g. to a chassis of the motor vehicle 2, by means of the fastening points 109.

FIG. 3 shows a plug-in direction E, in which the plug-in connector part 12 can be plugged into the plug-in opening 100 in the housing 10.

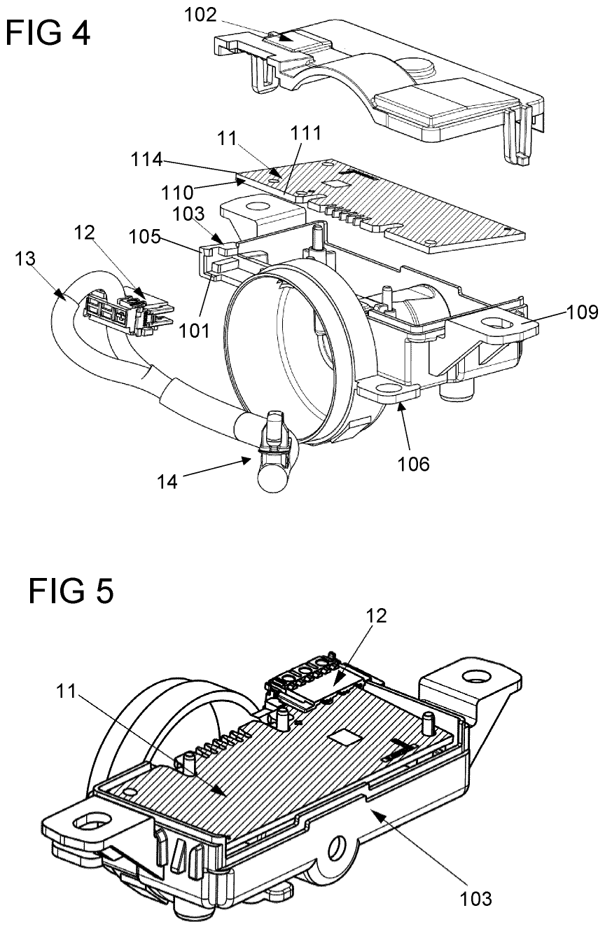

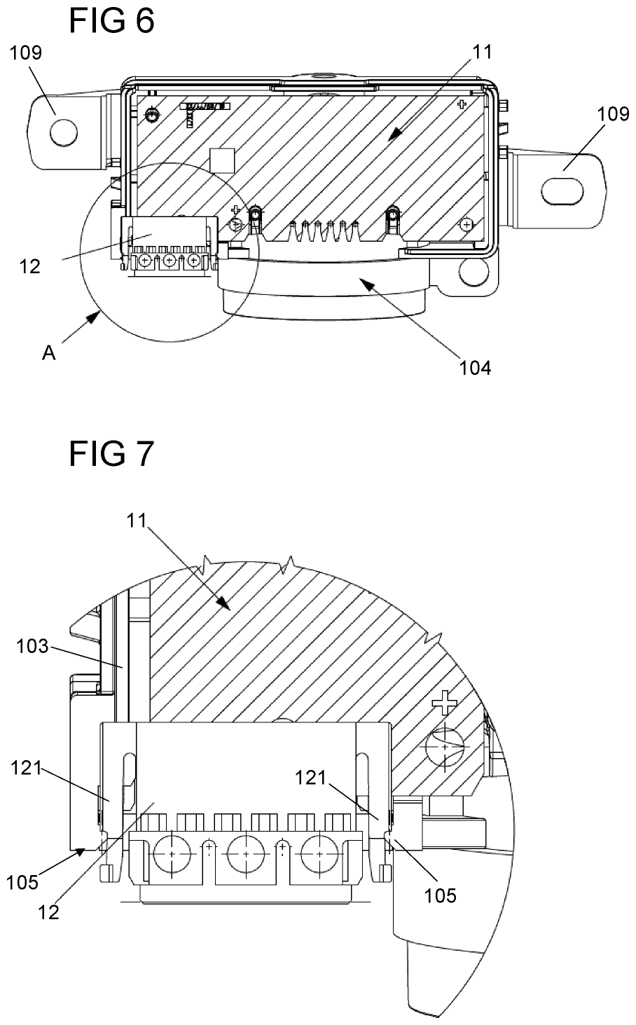

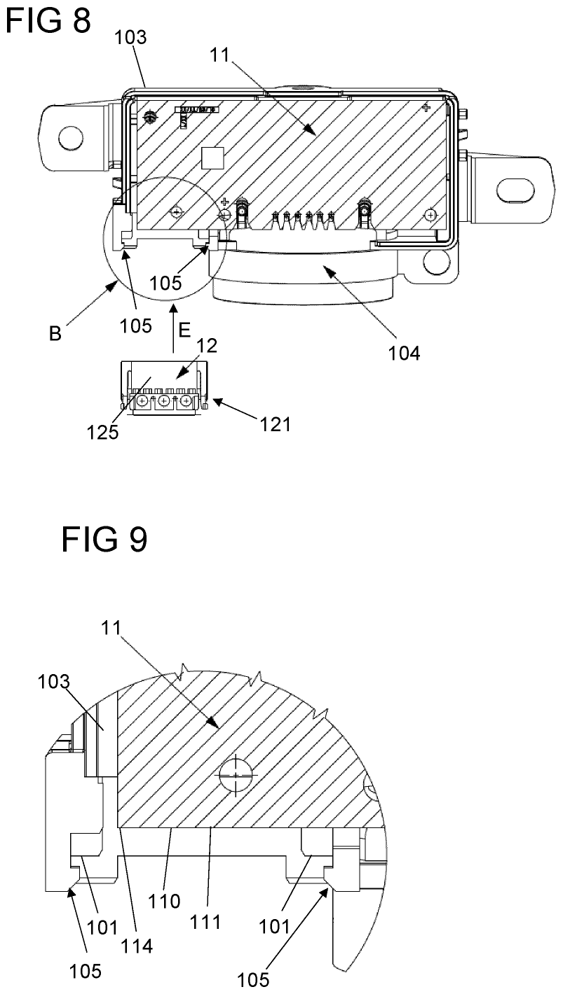

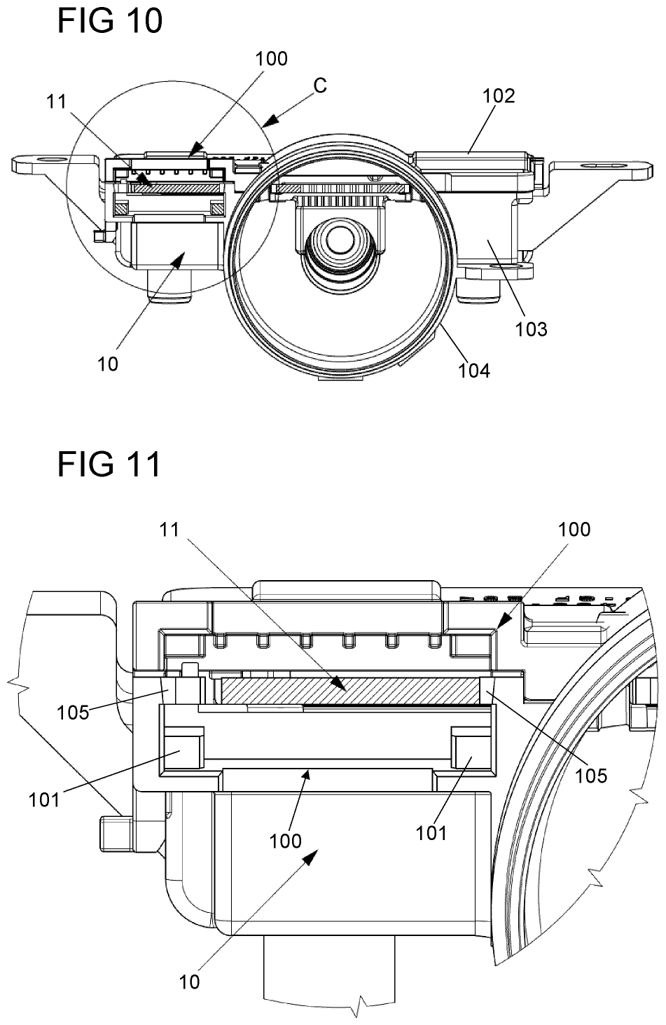

As shown on the basis of FIGS. 4-11 in particular, the plug-in connecting device 1 further comprises a printed circuit board 11. In the example shown (in the mounted state), the printed circuit board 11 is arranged in the housing 10 and fastened thereto. The printed circuit board 11 supports a plurality of electrical and/or electronic modules for the motor controller (wherein, in general, other applications are also conceivable).

The printed circuit board 11 is flat and level. The printed circuit board 11 comprises two main surfaces, which are the two largest surfaces of the printed circuit board 11 and extend in parallel with one another. The printed circuit board 11 further comprises edges between the main surfaces. The printed circuit board 11 comprises a plug-in portion 110 in the region of an edge 111 of the printed circuit board 11. Here, the edge 111 merges into one main surface by way of a rim and merges into the other main surface by way of another rim. The edge 111 is level in the region of the plug-in portion 110. The edge 111 is formed by a surface that extends perpendicularly to the main surfaces.

When the plug-in connector part 12 is plugged into the plug-in opening 100 in the housing 10 in the plug-in direction E, it electrically contacts the plug-in portion 110 of the printed circuit board 11. The plug-in connection is therefore configured as printed circuit board edge contacting.

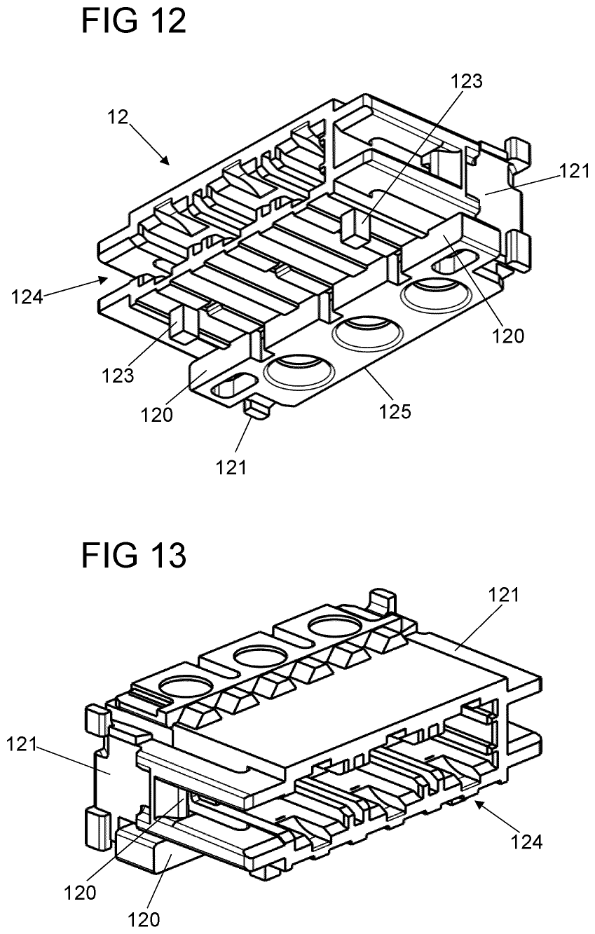

In order to keep the mechanical load on the printed circuit board 11 as low as possible here, it is provided that the plug-in connector part 12 comprises at least one stop 120, which strikes at least one stop 101 on the housing 10 in the plug-in direction E. In the present case, the plug-in connector part 12 comprises two stops 120, which are shown in FIG. 12 in particular, and the housing 10 comprises two stops 101, which are shown in FIGS. 4, 9 and 11 in particular.

The stops 101 on the housing 10 are arranged within the collar 108, and specifically on opposite sides in the present case. Here, the stops 101 are formed on the (second) housing part 103 on which the fastening points 109 are also provided. Stop surfaces of the stops 101 are in the same plane.

The stops 120 on the plug-in connector part 12 are formed on edge regions of a body 125 of the plug-in connector part 12. Stop surfaces of the stops 120 on the plug-in connector part 120 are in the same plane. As shown in FIG. 12 in particular, the stops 120 are formed by a step on the body 125.

When the plug-in connector part 12 is plugged into the plug-in opening 100 in the plug-in direction E, the stops 120 on the plug-in connector part 12 strike the stops 101 on the housing 10 before the plug-in connector part 12 comes into contact with the edge 111 of the printed circuit board 11. This means that there is always spacing between the body 125 of the plug-in connector part 12 and the edge 111 of the printed circuit board. This can prevent forces from being introduced into the printed circuit board 11. As shown on the basis of FIG. 9 in particular, the stops 101 on the housing 10, when viewed in the plug-in direction E, are arranged in front of the edge 111 of the printed circuit board 11.

The plug-in connector part 12 also latches to the housing 10. For this purpose, in the present example, latch elements 105 are formed on the housing 10; see FIGS. 4, 7, 9 and 11 in particular. The latch elements 105 are configured to latch to, and thus lock to, a latch element 121 formed on the plug-in connector part 12 in order to prevent the plug-in connector part 12 from being pulled out counter to the plug-in direction E. The latch elements 121 of the plug-in connector part 12 are each in the form of a flexible latch arm. The latch arms are configured to resiliently snap behind the relevant latch element 105 on the housing 10, which is configured as a latch rim, when plugging the plug-in connector part 12 into the plug-in portion 110 of the printed circuit board 11. The latch rims are also formed on the (second) housing part 103 on which the fastening points 109 are also provided. The latch arms are formed on opposite sides of the body 125 of the plug-in connector part 12.

As shown on the basis of FIG. 11 in particular, the latch elements 105 on the housing 10 are arranged in a plane together with the printed circuit board 11. The latch elements 105 on the housing 10 are arranged to be flush with the printed circuit board 11. In the present case, they also have (approximately) the same thickness in a direction perpendicular to the main surfaces of the printed circuit board 11. This arrangement can prevent the plug-in connector part 12 from tilting owing to tensile loads.

As shown e.g. on the basis of FIGS. 5 to 11, the plug-in portion 110 of the printed circuit board 11 is arranged at a corner 114 of the printed circuit board 11. In the plugged-in state, the plug-in connector part 12 accordingly engages around the corner 14 of the printed circuit board 11. Therefore, a receptacle 124 of the plug-in connector part 12, in which the plug-in portion 110 of the printed circuit board 11 can be received (and is received in the mounted state), is open on one side (viewed perpendicularly to the plug-in direction E) and closed on an opposite side; see FIGS. 12 and 13 in particular. The plug-in connector part 12 thus engages around the printed circuit board 11 on the two main surfaces and on two edges 111 that are perpendicular to one another. One of the latch arms (latch elements 121) is formed on the open side and the other is formed on the opposite, closed side.

FIG. 12 also shows two guide projections 123, which protrude from the body 125. The guide projections 123 guide the body 125 of the plug-in connector part 12 into the plugged-in position. In the process, the guide projections 123 slide along surfaces which lead from the stops 101. Furthermore, the guide projections are supported on an inner surface of the collar 108 and thus prevent the plug-in connector part 12 from tilting relative to the printed circuit board 11.

In the plugged-in state, the plug-in connector part is mounted on the printed circuit board 11 in a floating manner.

Optionally, a gap in the plug region can be minimized by grooves being milled into the printed circuit board and/or the body 125 of the plug-in connector part 12, or made in another way. The body 125 of the plug-in connector part 12 can be made of comparatively soft material, for example a softer material than the housing 10. For transport purposes, a stopper can be plugged into the plug-in opening 100.

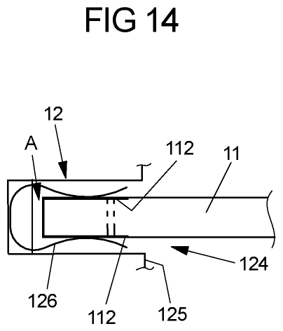

The plug-in connector part 12, which is shown in FIGS. 12 and 13 in particular, comprises, by way of example, receptacles and terminals for three contacts 126; see the schematic view in FIG. 14. The contacts 126 are in the form of spring contacts. The contacts are arranged in the receptacle 124 in the mounted state. The contacts 126 are in contact with contact surfaces 112 in the plug-in portion 110 of the printed circuit board 11. In the present case, the contact surfaces 112 are provided on opposite sides of the printed circuit board 11 for each of the contacts 126 of the plug-in connector part 12. The opposite contact surfaces 112 are electrically interconnected, e.g. by a via, shown in FIG. 14 by dashed lines. The via can be used to increase the thermal availability. The via can be arranged beside or behind the contact surfaces 112, or on the contact surfaces 112. Optionally, the via is filled with resin or copper and/or covered with a copper layer (on one side or both sides). Furthermore, a surface can be connected to an inner layer of the printed circuit board 11, e.g. as a thermal capacitor.

The contact surfaces 112 of the printed circuit board 11 are gold-coated. The contact surfaces 112 are also tin-plated over the gold layer. The contacts 126 of the plug-in connector part 12 are likewise tin-plated. For example, paste printing as part of the SMT process is an option for tin-plating the contact surfaces 112, in this case, for example, by doctoring with a template or by dispensing using a needle. In the process, the tin can be applied over the surface in order to achieve the greatest possible layer thickness, or over a reduced surface area for homogeneous planarity, wherein triangles, grids or frames can be used, for example. It is also possible to equip the printed circuit board 11 with tin preforms and to melt them, e.g. in a reflow process or by inductive soldering. Selective soldering processes are also conceivable, e.g. laser soldering or piston soldering, with the added tin solder being in the form of a wire or preform.

### LIST OF REFERENCE NUMERALS

1 Plug-in connecting device
10 Housing
100 Plug-in opening
101 Stop
102 First housing part
103 Second housing part
104 Motor receptacle
105 Latch element
106 Holder
108 Collar
109 Fastening point
11 Printed circuit board
110 Plug-in portion
111 Edge
112 Contact surface
114 Corner
12 Plug-in connector part
120 Stop
121 Latch element
123 Guide projection
124 Receptacle
125 Body
126 Contact
13 Cable
14 Strain relief device
2 Motor vehicle
21 Door
22 Vehicle seat
23 Control unit
3 Adjustment apparatus
30 Motor
A Spacing
E Plug-in direction

1. A plug-in connecting device for a motor vehicle, comprising
a housing comprising a plug-in opening,
a printed circuit board that is arranged in the housing and comprises a plug-in portion in the region of an edge of the printed circuit board, and
a plug-in connector part which can be plugged into the plug-in opening in the housing in a plug-in direction such that it electrically contacts the plug-in portion of the printed circuit board,
wherein the plug-in connector part comprises at least one stop, which strikes at least one stop on the housing in the plug-in direction.

2. The plug-in connecting device according to claim 1, wherein the at least one stop on the housing and the at least one stop on the plug-in connector part are configured such that the at least one stop on the plug-in connector part strikes the at least one stop on the housing when being plugged-in in the plug-in direction into the plug-in opening before the plug-in connector part comes into contact with the edge of the printed circuit board.

3. The plug-in connecting device according to claim 1, wherein the at least one stop on the housing, when viewed in the plug-in direction, is arranged in front of the edge of the printed circuit board.

4. The plug-in connecting device according to claim 1, wherein the plug-in connector part comprises a body on which a plurality of contacts are mounted, wherein the body is spaced apart from the edge of the printed circuit board in a plugged-in state of the plug-in connector part when viewed in the plug-in direction.

5. The plug-in connecting device according to claim 1, wherein at least one latch element is formed on the housing, which latch element is configured to latch to at least one latch element formed on the plug-in connector part in order to prevent the plug-in connector part from being pulled out counter to the plug-in direction.

6. The plug-in in connecting device according to claim 5, wherein the at least one latch element on the housing is arranged in a plane together with the printed circuit board.

7. The plug-in connecting device according to claim 5, wherein the at least one latch element on the plug-in connector part is in the form of a flexible latch arm in order to resiliently snap behind the at least one latch element on the housing, which is configured as a latch rim, when plugging the plug-in connector part into the plug-in portion of the printed circuit board.

8. The plug-in connecting device according to claim 5, wherein the housing comprises two housing parts, wherein fastening points are configured for fastening the housing to another component on those housing parts on which the at least one latch element on the housing is also formed.

9. The plug-in in connecting device according to claim 1, wherein the housing comprises a collar, which is configured to laterally support the plug-in connector part in a plugged-in state.

10. The plug-in connecting device according to claim 1, wherein the plug-in connector part engages around a corner of the printed circuit board in a plugged-in state.

11. The plug-in connecting device according to claim 1, wherein a cable attached to the plug-in connector part is held on a holder of the housing by means of a strain relief device.

12. The plug-in connecting device according to claim 1, wherein at least one portion of the housing is inclined towards the printed circuit board in the region of the plug-in opening.

13. The plug-in connecting device according to claim 1, wherein the printed circuit board is rigidly connected to the housing.

14. The plug-in connecting device according to claim 1, wherein the housing comprises a motor receptacle for fastening a motor.

15. The plug-in connecting device according to claim 1, wherein a gold-plated surface of the printed circuit board is tin-plated in the region of the plug-in portion.

16. An adjustment apparatus, comprising the plug-in connecting device according to claim 1 and a motor mounted on the housing.

17. A motor vehicle, comprising the plug-in connecting device according to claim 1.
